(19) United States
(12) Patent Application Publication
(10) Pub. No.: US 2024/0373766 A1
(43) Pub. Date: Nov. 7, 2024

(54) Reversible Semimetal-Semiconductor Transition of Unconventional-Phase WS2 Nanosheets

(71) Applicant: City University of Hong Kong, Hong Kong (CN)

(72) Inventors: Hua ZHANG, Hong Kong (CN); Qiyuan HE, Hong Kong (CN); Wei ZHAI, Hong Kong (CN)

(21) Appl. No.: 18/359,090

(22) Filed: Jul. 26, 2023

Related U.S. Application Data
(60) Provisional application No. 63/499,753, filed on May 3, 2023.

(51) Int. Cl. H10N 70/00; H10N 70/20

(52) U.S. Cl. CPC H10N 70/8822; H10N 70/041; H10N 70/235; H10N 70/253

(57) ABSTRACT

A reversible phase transition in the whole semimetallic 1T′-tungsten disulfide (1T′-WS₂) is realizable by proton intercalation and deintercalation, resulting in a newly-discovered semiconducting WS₂ with a novel unconventional phase, denoted as 1T′_{d} phase. A transport modulation with an on/off ratio of over 10⁶ is realizable during the phase transition from the 1T′-WS₂ to 1T′_{d}-WS₂. A transistor utilizing the advantage of reversible phase transition is developed by using a 1T′-WS₂ nanosheet as a channel layer. A proton electrolyte contacts an edged circumference of the nanosheet for providing a reservoir of protons for proton intercalation and deintercalation of the nanosheet. The proton electrolyte is controllable by a gate-source voltage to intercalate or de-intercalate the nanosheet with protons for inducing a reversible phase transition over the nanosheet to thereby modify an electrical conductance of the channel layer or a spectral response of the channel layer to light.

### CROSS-REFERENCE TO RELATED APPLICATIONS

The present application claims priority to U.S. Provisional Patent Application No. 63/499,753, filed on May 3, 2023, which is hereby incorporated by reference in its entirety.

### FIELD OF THE INVENTION

This disclosure relates to a reversible phase transition between the 1T′ phase and the 1T′_{d} phase for a tungsten disulfide (WS₂) nanosheet. Particularly, this disclosure relates to a highly efficient reversible phase transition strategy via the proton intercalation and deintercalation of the WS₂ nanosheet, and to a transistor developed based on this strategy.

### BACKGROUND

Crystal phase, as one essential structural parameter beyond size, dimensionality, morphology, and facet, can determine the physicochemical properties of nanomaterials [1], [2]. As one of the powerful strategies in phase engineering of nanomaterials (PEN) [1], phase transition accompanied by the bandgap modulation has been widely explored in various materials owing to its great potential for diverse fundamental studies and applications [3]-[6]. In particular, phase transition of transition metal dichalcogenides (TMDs) is intriguing owing to their unique crystal-phase-dependent electronic structures, leading to fundamental studies in catalysis [7]-[8], (opto) electronics [4], [9], and condensed matter physics [10]-[12]. The phase transition of TMDs can be initialized by various methods [1], such as chemical modification [13], laser irradiation [14], and lithium-ion intercalation [15], [16]. Different from the transition metal tellurides, due to the large energy difference between the thermodynamically stable phase (e.g., 2H) and unconventional phase (e.g., 1T and 1T′) in other TMDs [17], the phase transition in TMDs can only be realized in either monolayers or localized domains [5], [15], [18]. Moreover, the associated undesirable structural damage, such as amorphization [19], vacancy generation [14], and compositional alteration [20], could lead to a poor reversibility of the phase transition. Differently, the reversible phase transition of TMDs has been demonstrated in the transition metal tellurides under electrostatic gating by taking advantage of the relatively small energy difference between their 2H and 1T′ phases [4], [5], [17], [21]. However, a recent study has indicated that such strong gate modulation can induce the formation of tellurium (Te) vacancies [20]. Alternatively, intercalation strategies take advantage of the layered structure of TMDs by intercalating various guest species into the van der Waals gaps to achieve a phase transition in bulk crystals [6], [15], [22], [23]. However, the reported intercalation methods, either chemical or electrochemical [15], [24]-[27], can only induce phase transition in localized domains together with undesirable structural damage and limited reversibility. Despite these research efforts, the phase transition in TMDs across the single-crystal level with high controllability and reversibility remains a great challenge. Compared to the commonly used guest species, such as metal ion [25], metal atom [28], and molecule [29], the smallest and lightest ion, i.e. a proton, has attracted intensive research attention owing to its superior ability in tuning the physicochemical properties of nanomaterials for various applications [3], [30]-[32]. For example, the hydrogenation of metal oxides via proton intercalation has been achieved, leading to the modulation of their properties [3]. [30], [33], [34].

### SUMMARY OF THE INVENTION

Disclosed herein is a highly efficient reversible phase transition strategy via the proton intercalation and deintercalation in a microcell device (subplot (a) of FIG. 1), in which the high electron injection and extraction densities (˜1 e per formula unit of WS₂) can induce a reversible phase transition of the semimetallic 1T′-WS₂ (subplot (b) of FIG. 1) across a single-crystalline nanosheet. Based on the in-situ and ex-situ characterizations, the resulting structure after the phase transition of 1T′-WS₂ has been identified as a new distorted octahedral phase, denoted as 1T′_{d}. Impressively, the obtained 1T′_{d}-WS₂ can be completely transferred to 1T′-WS₂ after the proton deintercalation, indicating that the reversible phase transition has been achieved in the single-crystalline 1T′-WS₂ nanosheet via the proton intercalation and deintercalation. Moreover, a transport modulation with an on/off ratio of >10⁶ has been realized during the phase transition from the 1T′-WS₂ to 1T′_{d}-WS₂.

Also disclosed herein is a transistor for utilizing the advantage of reversible phase transition offered by 1T′-WS₂. The transistor comprises a source electrode, a drain electrode, a gate electrode, a 1T′-WS₂ nanosheet and a proton electrolyte. The 1T′-WS₂ nanosheet forms a channel layer connecting the source and drain electrodes. The nanosheet has an edged circumference. The proton electrolyte is in contact with the edged circumference for providing a reservoir of protons for proton intercalation and deintercalation of the nanosheet. The gate electrode contacts the proton electrolyte without contacting the nanosheet such that the proton electrolyte is controllable by a gate-source voltage applied between the gate electrode and the source electrode to intercalate or de-intercalate the nanosheet with protons for inducing a reversible phase transition over the nanosheet. The occurrence of reversible phase transition thereby modifies an electrical conductance of the channel layer or a spectral response of the channel layer to light.

In certain embodiments, the 1T′-WS₂ nanosheet comprises at least two layers.

In certain embodiments, the 1T′-WS₂ nanosheet is uniformly crystalline.

In certain embodiments, the proton electrolyte is an aqueous proton electrolyte. The aqueous proton electrolyte may be an inorganic acid. The inorganic acid may comprise sulfuric acid, nitric acid, hydrochloric acid, phosphoric acid, acetic acid, or a combination thereof.

In certain embodiments, the proton electrolyte is an organic proton electrolyte. The organic proton electrolyte may be bis(trifluoromethane) sulfonimide (TFSI) dissolved in liquid poly(ethylene glycol).

In certain embodiments, the proton electrolyte is a proton-containing solid electrolyte.

In certain embodiments, each of the drain and source electrodes comprises gold, chromium, or a combination thereof.

In certain embodiments, the gate electrode comprises platinum.

Further disclosed herein is a method of preparing a 1T′_{d}-WS₂ nanosheet. The method comprises: providing any of the embodiments of the disclosed transistor; and applying the gate-source voltage between the gate electrode and the source electrode thereby forming the 1T′_{d}-WS₂ nanosheet.

In certain embodiments, each of the 1T′-WS₂ nanosheet and the 1T′_{d}-WS₂ nanosheet comprises at least two layers.

In certain embodiments, each of the 1T′-WS₂ nanosheet and the 1T′_{d}-WS₂ nanosheet is uniformly crystalline.

In certain embodiments, the gate-source voltage is 1.1V or above.

Other aspects of the present invention are disclosed as illustrated by the embodiments hereinafter.

### BRIEF DESCRIPTION OF THE DRAWINGS

The above and other objects and features of the present disclosure will become apparent from the following description of the disclosure, when taken in conjunction with the accompanying drawings.

FIG. 1 schematically illustrates reversible phase transition of 1T′-WS₂ conducted in a microcell device, where: subplot (a) depicts a schematic illustration of the microcell device used for the reversible phase transition of 1T′-WS₂ driven by the proton intercalation and deintercalation, respectively; and subplot (b) depicts the atomic structural models of 1T′-WS₂ and 1T′_{d}-WS₂ during the reversible phase transition.

FIG. 2 illustrates construction of microcell devices used in measurements during the electron injection and extraction as well as measured results of these device, where: subplot (a) provides optical images of a microcell device: the overall set-up with three electrodes in view (i), the high-magnification image of the microcell device with a droplet of electrolyte in view (ii), and the device fabricated with a mechanically exfoliated 1T′-WS₂ nanosheet with a window opened in the poly(methyl methacrylate) (PMMA) passivation layer, such that two opposite edges and the basal plane of 1T′-WS₂ nanosheet are exposed to the electrolyte, in view (iii); and subplot (b) provides typical drain-source current (I_{ds}) and gate current (I_{g}) measured in the fabricated microcell device of 1T′-WS₂ during the charge injection and extraction processes in a 0.5M H₂SO₄ aqueous solution.

FIG. 3 provides a characterization of the phase transition of 1T′-WS₂ nanosheets, where: subplot (a) plots in-situ Raman characterization of the 1T′-WS₂ nanosheet during the proton intercalation and deintercalation in a 0.5M H₂SO₄ aqueous solution; subplot (b) plots in-situ photoluminescence characterization of the 1T′-WS₂ nanosheet during the proton intercalation and deintercalation in a 0.5M H₂SO₄ aqueous solution; subplot (c) plots in-situ Raman spectra obtained at different gate potentials, showing a highly reversible phase transition process; and subplot (d) plots the percentage of 1T′ phase in the WS₂ nanosheet at different gate potentials.

FIG. 4 provides a structural characterization of 1T′-WS₂ and 1T′_{d}-WS₂ nanosheets, where: subplot (a) shows a selected area electron diffraction (SAED) pattern of the 1T′-WS₂ nanosheet obtained via mechanical exfoliation of a bulk 1T′-WS₂ crystal; subplot (b) depicts a high-angle annular dark-field scanning transmission electron microscope (HAADF-STEM) image of the nanosheet of subplot (a); subplot (c) plots the corresponding FFT pattern of the HAADF-STEM image shown in subplot (b); subplot (d) shows a SAED pattern of the 1T′-WS₂ nanosheet after proton intercalation; subplot (c) depicts a HAADF-STEM image of the nanosheet of subplot (d); subplot (f) plots the corresponding FFT pattern of the HAADF-STEM image in subplot (c); subplot (g) depicts a relative displacement map of W columns in WS₂ nanosheet after proton intercalation with respect to the 1T′ lattice used as reference; subplot (h) shows a displacement map derived from subplot (g), with the displacement of every W columns indicated by circles; and subplot (i) plots magnitudes of displacements obtained in subplot (h) along horizontal (X) and vertical (Y) directions, the average magnitudes of the columns being 0.11, 0.13, 0.03 and 0.03 Å, respectively.

FIG. 5 depicts different types of microcell devices used in our work, where: subplot (a) provides an optical image of the overall set-up of a three-electrode microcell device; subplot (b) depicts the electric device fabricated with a mechanically exfoliated 1T′-WS₂ nanosheet used in the three-electrode microcell device shown in subplot (a); subplot (c) provides an optical image of the overall set-up of a four-electrode microcell device; subplot (d) depicts the electric device fabricated with a mechanically exfoliated 1T′-WS₂ nanosheet used in the four-electrode microcell device shown in subplot (c); subplot (e) provides an optical image of the overall set-up of a microcell device with in-situ Raman; and subplot (f) provides the high-magnification optical image of the microcell device shown in subplot (c).

FIG. 6 illustrates a typical fabrication procedure of microcell devices.

FIG. 7 depicts an equivalent circuit diagram of a three-electrode microcell device.

FIG. 8 plots gate currents measured during the proton intercalation and

deintercalation processes shown in subplot (b) of FIG. 2, where subplots (a) and (b) show the curves of electron injection and of electron extraction, respectively.

FIG. 9 illustrates typical electrical characteristics of 1T′-WS₂ nanosheets under a variety of conditions, where: subplot (a) depicts typical drain-source current (I_{ds}) curves of 1T′-WS₂ nanosheets without a window (case I) and with a window on the basal plane (case II) swept in a 0.5M H₂SO₄ aqueous solution; and subplot (b) depicts typical I_{g} VS. V_{g} curves of 1T′-WS₂ nanosheets swept in a 0.5M H₂SO₄ aqueous solution without a window (case I) and with a window on the basal plane (case II).

FIG. 10 depicts typical drain-source current (I_{ds}) and gate current (I_{g}) curves of 1T′-WS₂ nanosheets in microcell devices tested in electrolytes containing different ions, where: subplot (a) depicts the curves of 1T′-WS₂ nanosheets tested in Li-ion polymer gel; and subplot (b) depicts the curves of 1T′-WS₂ nanosheets tested in 0.5M deuterosulfuric acid solution.

FIG. 11 plots I_{ds} vs. I_{g} curves obtained in a cycling test of 1T′-WS₂ microcell device during the proton intercalation and deintercalation.

FIG. 12 plots the equivalent circuit diagram of four-electrode microcell device.

FIG. 13 plots Raman spectra of the 1T′-WS₂ nanosheet at different gate potentials, where: subplot (a) provides a Raman spectrum of the 1T′-WS₂ nanosheet measured at V_{g}=0.81V; and subplot (b) provides a Raman spectrum of the 1T′-WS₂ nanosheet measured at V_{g}=0.82V.

FIG. 14 depicts typical drain-source current (I_{ds}) and gate current (I_{g}) curves of 1T′-WS₂ nanosheets in microcell devices tested in the organic proton electrolyte, where: subplot (a) depicts the curves of the microcell device swept in an organic proton electrolyte; and subplot (b) depicts the curves, in logarithmic scale, of the 1T′-WS₂ nanosheet before and after the proton intercalation.

FIG. 15 provides Raman characterization of the 1T′-WS₂ nanosheets after the proton intercalation in different proton solutions.

FIG. 16 plots average intensity profiles of W columns in 1T′-WS₂ nanosheets (a) before phase transition as shown in subplot (a), and after phase transition as shown in subplot (b), where the intensity profiles in subplots (a) and (b) correspond to the rectangular regions in subplots (b) and (e) of FIG. 4, respectively.

FIG. 17 plots the inverse Fourier transform of the FFT pattern in subplot (f) of FIG. 4 after damping the amplitude of the new superspots.

FIG. 18 provides a structural characterization of 1T′-WS₂ nanosheet after proton intercalation, where: subplot (a) provides a TEM image of the 1T′-WS₂ nanosheet after the proton intercalation; and subplots (b), (c) and (d) provide SAED patterns of the corresponding regions as marked in the subplot (a).

FIG. 19 exemplarily depicts a structure of a transistor as disclosed herein.

FIG. 20 depicts a flowchart showing exemplary steps of a method, as disclosed herein, of preparing a 1T′_{d}-WS₂ nanosheet.

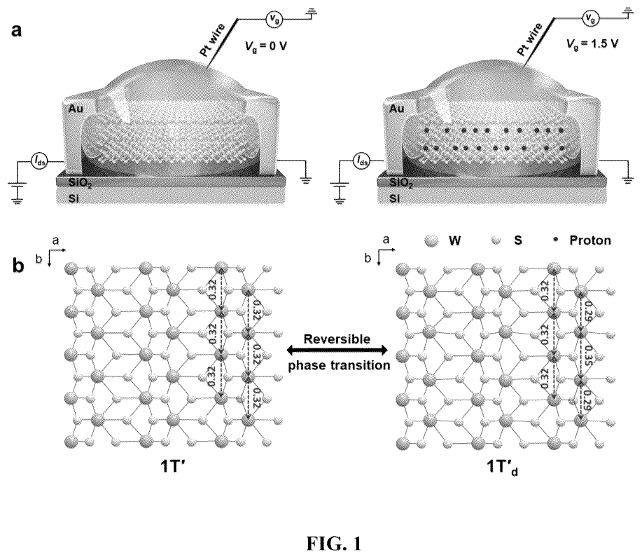

Skilled artisans will appreciate that elements in the figures are illustrated for simplicity and clarity and have not necessarily been depicted to scale.

### DETAILED DESCRIPTION

Throughout the present disclosure, unless the context requires otherwise, the word “comprise” or variations such as “comprises” or “comprising”, will be understood to imply the inclusion of a stated integer or group of integers but not the exclusion of any other integer or group of integers. It is also noted that in this disclosure and particularly in the claims and/or paragraphs, terms such as “comprises”, “comprised”, “comprising” and the like can have the meaning attributed to it in U.S. Patent law; e.g., they can mean “includes”, “included”, “including”, and the like; and that terms such as “consisting essentially of” and “consists essentially of” have the meaning ascribed to them in U.S. Patent law, e.g., they allow for elements not explicitly recited, but exclude elements that are found in the prior art or that affect a basic or novel characteristic of the present invention.

Furthermore, throughout the present disclosure and claims, unless the context requires otherwise, the word “include” or variations such as “includes” or “including”, will be understood to imply the inclusion of a stated integer or group of integers, but not the exclusion of any other integer or group of integers.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

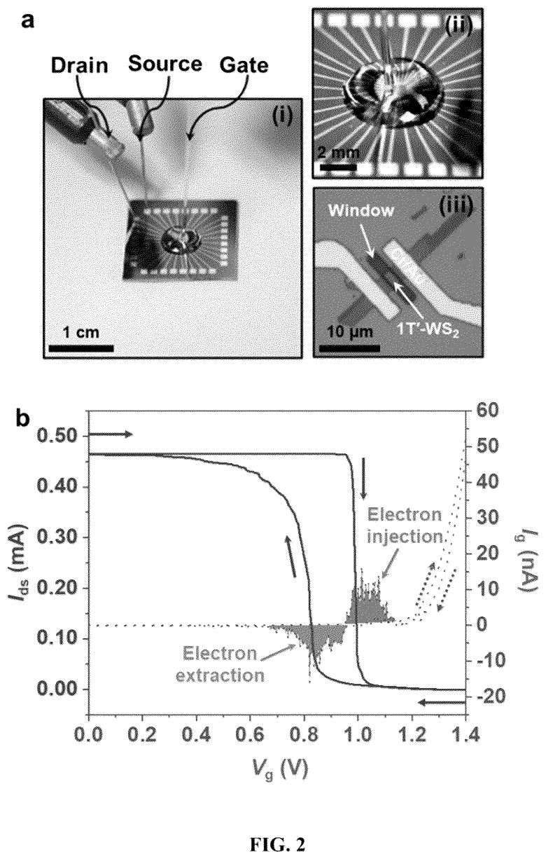

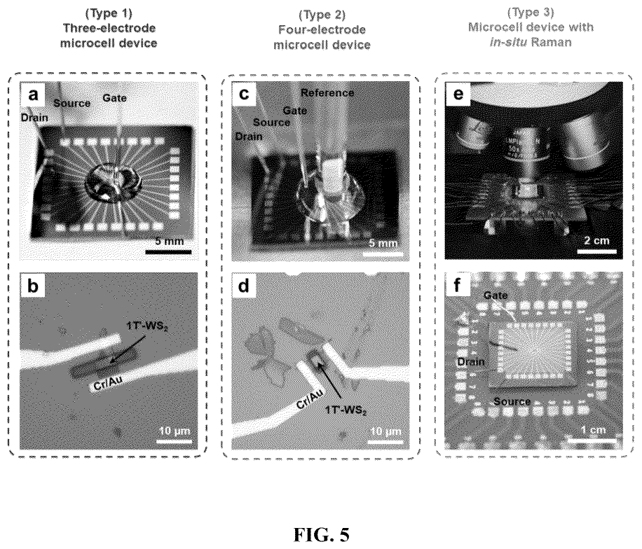

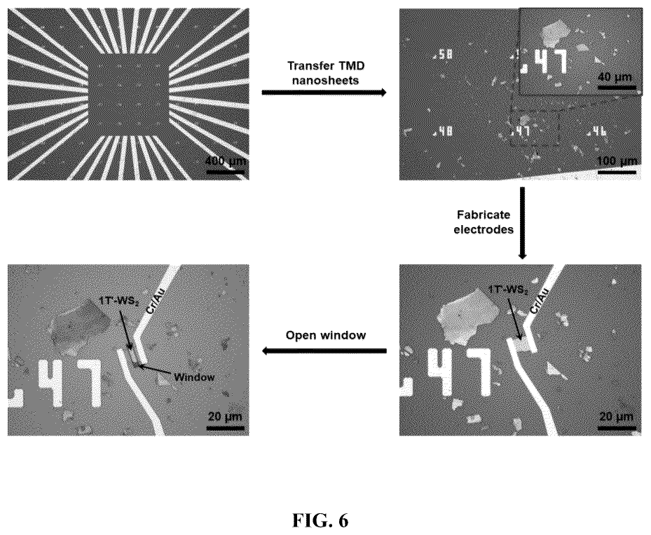

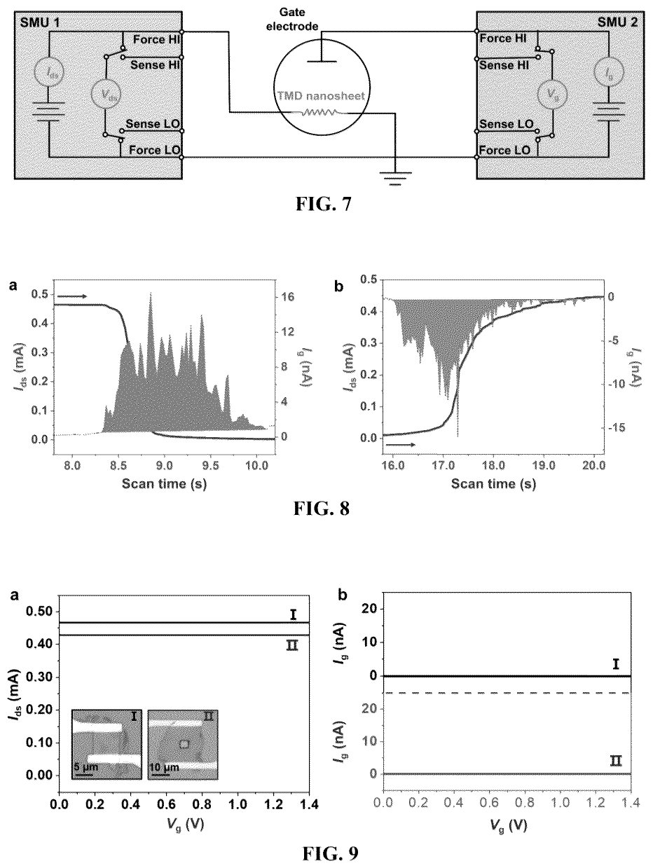

The reversible phase transition driven by the proton intercalation and deintercalation in 1T′-WS₂ nanosheets was conducted in microcell devices (subplot (a) of FIG. 2; FIG. 5; FIG. 6). FIG. 7 shows the detailed equivalent circuit diagram of the three-electrode microcell device shown in subplot (a) in subplot (a) of FIG. 2 and subplot (a) of FIG. 5, in which the mechanically exfoliated 1T′-WS₂ nanosheet, Pt wire, and evaporated Cr/Au electrodes are used as the channel material, gate, and drain and source electrodes, respectively. FIG. 2, subplot (b), shows the typical drain-source current (I_{ds}) and the gate current (I_{g}) obtained in a 0.5M H₂SO₄ aqueous solution used as the electrolyte. Initially, the 1T′-WS₂ maintains a stable and high conductance as the gate potential (V_{g}) ranging from 0 to 0.96 V, which is consistent with the semimetallic feature of 1T′-WS₂ under gating [35]. When the V_{g} exceeds 0.96V, the I_{ds} reduces dramatically together with the appearance of positive spikes in I_{g} (as shown in subplot (b) of FIG. 2, which corresponds to the electron injection into the 1T′-WS₂ nanosheet. When the V_{g} is scanned back from 1.4V toward 0V, the I_{ds} value increases and finally reaches the initial current value along with negative spikes in I_{g} (FIG. 2, subplot (b)), which corresponds to the electron extraction from the WS₂ nanosheet. By integrating the gate current profile in subplot (b) of FIG. 2 to calculate the numbers of injected and extracted electrons, it is found that the number of injected electrons is nearly equal to that of the extracted ones (FIG. 8). It is also worth mentioning that both the electron injection and extraction densities in 1T′-WS₂ are ˜1 e per formula unit of WS₂, which are ˜5 times that obtained in the most efficient reversible electron injection and extraction strategy reported previously, i.e. the electrostatic electron injection and extraction in MoTe₂ [36].

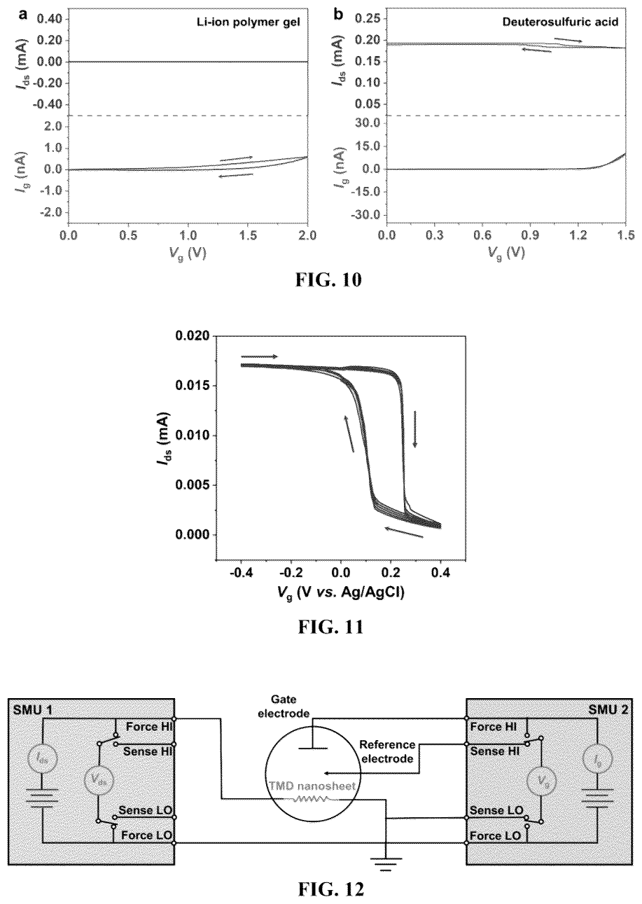

To further clarify the origin of such a significant electrical transport modulation and the charge transfer process at the solid-electrolyte interface (SEI), microcell devices without a window (FIG. 9, subplot (a), case I) and with a window on the basal plane (FIG. 9, subplot (a), case II) were fabricated. It is worth mentioning that the electrical transport modulation and the electron transfer have not occurred on the device without a window (FIG. 9, subplot (a), case I; FIG. 9, subplot (b), case I), suggesting the effective passivation of the PMMA layer. When a window, which is exposed to the electrolyte, is open only on the basal plane of the 1T′-WS₂ nanosheet (FIG. 9, subplot (a), case II), no electrical transport modulation and electron transfer are observed (FIG. 9, subplot (a), case II; FIG. 9, subplot (b), case II), indicating that the electrostatic gating has no effect on the transport modulation of the 1T′-WS₂ nanosheet [37]. However, the transport modulation and electron transfer can occur in a device with edge exposed to the electrolyte (FIG. 2, subplot (b)), indicating that the transport modulation and electron transfer originate from the proton intercalation and deintercalation in the van der Waals gaps 1T′-WS₂ nanosheet via its edge. In addition, when the V_{g} exceeds 0.96V, the decay slope of I_{ds} in subplot (b) of FIG. 2 can reach below 30 mV/dec, which are much lower than the room-temperature Boltzmann limit of 60 mV/dec in electrostatic gating [38], further confirming that the electrical transport modulation is not from the electrostatic gating. Based on the aforementioned experiments and the previous on-chip studies on the TMD intercalation [27], it is believed that the charge injection and extraction in H₂SO₄ aqueous solution can be attributed to the intercalation and deintercalation of protons, respectively, which is the only cation in the electrolyte solution, in the van der Waals gaps of the layered 1T′-WS₂ nanosheets. It is worth mentioning that our result is similar to the phase transition in metal oxides induced by hydrogenation in which protons are intercalated in their atomic lattices [3], [30]-[34]. Our additional experiments in the other ion-containing electrolytes demonstrate that only the electrolyte containing protons leads to this reversible electrical transport modulation (FIG. 10). Additionally, unlike other ionic or molecular intercalations, which normally damage the structural integrity of 2D crystals [14]-[16], [20], the proton intercalation and deintercalation are reversible, as evidenced by the cycling test (FIG. 11).

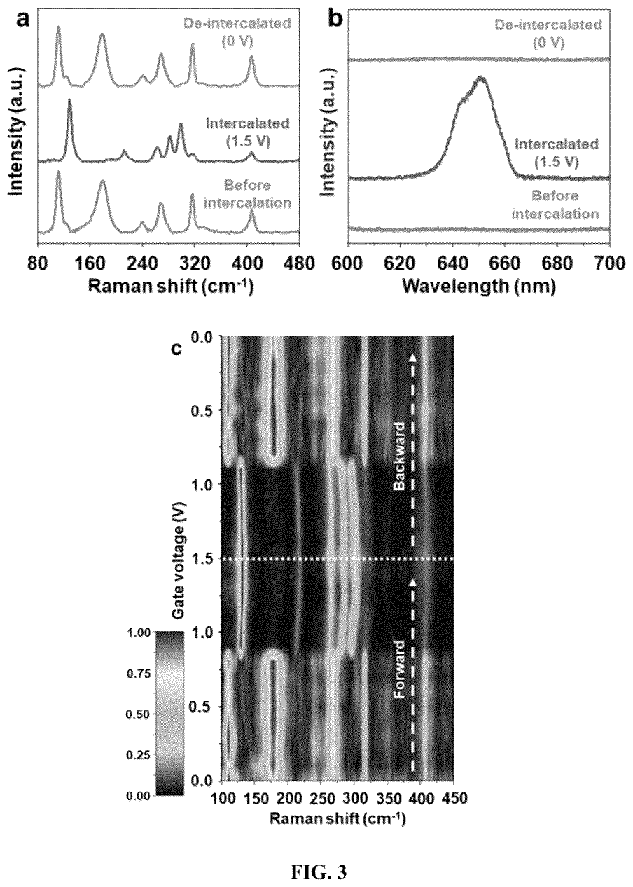

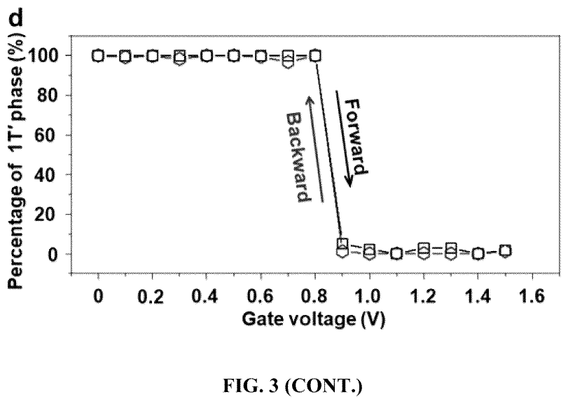

Previous studies have highlighted the structural diversity of TMD crystals and the importance of the electron injection in the modulation of their crystal structures [1], [2]. To further understand how much electron injection and extraction densities can lead to such large transport modulation, in-situ Raman characterization was employed to characterize the structural evolution of 1T′-WS₂ during the proton intercalation and deintercalation (subplots (c) and (f) of FIG. 5). Subplot (a) of FIG. 3 shows the Raman spectra of the 1T′-WS₂ nanosheet before intercalation (V_{g}=0V), the intercalated nanosheet (V_{g}=1.5V), and the de-intercalated nanosheet (V_{g}=0V) in 0.5M H₂SO₄ aqueous electrolyte. The 1T′-WS₂ nanosheet before intercalation shows a characteristic Raman spectrum of 1T′-WS₂, indicating the high phase purity of the exfoliated nanosheets [35]. When the nanosheet is intercalated (V_{g}=1.5V), the peaks indexed to 1T′-WS₂ disappear entirely. Instead, a new set of distinct Raman peaks located at 128, 212, 263, 282, 298, 317 and 407 cm⁻¹ emerged, indicating a crystal structure change of the WS₂ nanosheet. When the V_{g} is swept back to 0V, the nanosheet is de-intercalated, and the corresponding Raman spectrum is identical to that of the 1T′-WS₂ nanosheet before intercalation, suggesting the high reversibility of such a structural transition. It is worth mentioning that the set of Raman peaks emerged at V_{g}=1.5V is different from that in previously reported WS₂ polymorphs, indicating the formation of a new phase of WS₂. As shown in the in-situ photoluminescence (PL) measurement (subplot (b) of FIG. 3), there is no PL signal on the 1T′-WS₂ nanosheet before intercalation, which originates from its semimetallic nature [35]. In contrast, the intercalated WS₂ nanosheet exhibits a semiconducting characteristic with a strong PL peak of ˜650 nm at V_{g}=1.5V (subplot (b) of FIG. 3). After V_{g} is swept back to 0V, the absence of the PL signal (subplot (b) of FIG. 3) manifests the de-intercalated nanosheet has transformed from the semiconducting phase to the semimetallic 1T′ phase, indicating the high reversibility of the phase transition.

The phase transition processes can also be visualized in a voltage mapping in which the Raman spectra of the WS₂ nanosheet were recorded during the V_{g} swept from 0 to 1.5 V with an interval of 0.1V. To make the phase transition visible, Raman intensities obtained at different voltages have been normalized. As shown in FIG. 3, subplot (c), the WS₂ nanosheet remains in the pristine 1T′ phase and shows its characteristic peaks at 112, 179, 239, 268, 316, and 407 cm⁻¹ when a constant V_{g} ranging from 0 to 0.8 V was applied. At V_{g}=0.9V, the Raman peaks corresponding to 1T′-WS₂ disappear while those located at 129, 212, 263, 282, 298, 317 and 407 cm⁻¹ emerged which can be assigned to the new phase. Such a phase transition process is consistent with the sharp drop of I_{ds} in the electrical transport measurement (FIG. 2, subplot (b)). Based on the aforementioned PL and Raman spectra, the observed large electrical transport modulation shown in FIG. 2, subplot (b), can be attributed to the modulation of electronic band structures from semimetal to semiconductor. The aforementioned phase transition is different from that induced by electrostatic gating, in which the phase percentages gradually change and also strongly correlate with the gate potential [5].

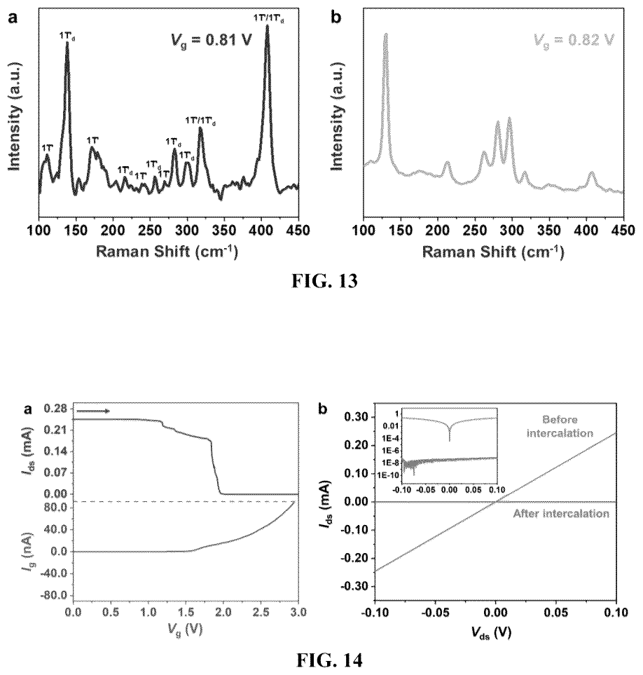

As shown in FIG. 3, subplot (c), the nanosheet maintains the same new phase when the V_{g} ranges from 0.9 to 1.5V. As the V_{g} is swept back to 0.8V, the Raman peaks indexed to the new phase disappear and the peaks belonging to 1T′-WS₂ reappear, indicating the phase of WS₂ nanosheet is transformed back to the original 1T′ phase. The percentage of the 1T′ phase at different voltage is estimated by

$$\frac{{S}_{{IT}^{′}}}{{S}_{{IT}^{′}} + {S}_{{IT}_{d}^{′}}} ,$$

where S_{1T′} and S_{1T′}_{_{d}} represent the areas of Raman peaks assigned to the 1T′ phase at 112 cm⁻¹ and the new 1T′_{d} phase at 128 cm⁻¹. As shown in FIG. 3, subplot (d), at the V_{g} ranging from 0 to 0.8 V, the percentage of 1T′ phase is 100%. However, it approaches ˜0% at the V_{g} ranging from 0.9 to 1.5 V. To further identify the phase transition process at the V_{g} ranging from 0.8 and 0.9 V, detailed Raman characterization was carried out at V_{g}=0.81V and 0.82V (FIG. 13). The Raman spectrum recorded at V_{g}=0.81V demonstrates the coexistence of the 1T′ phase and the new phase (FIG. 13, subplot (a)), while the phase of the WS₂ nanosheet completely transforms to the new phase when the V_{g} slightly increases to 0.82V from 0.81V (FIG. 13, subplot (b)).

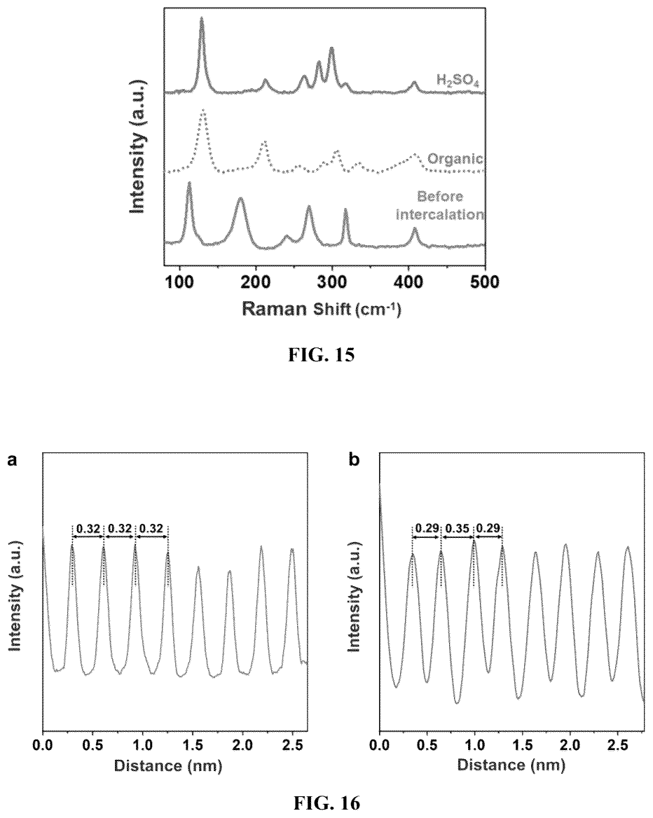

The highly reversible phase transition in the aqueous proton electrolyte hinders the ex-situ structural characterization of the new 1T′_{d} phase obtained after the proton intercalation of the 1T′-WS₂. To stabilize the intercalated structure, we performed the proton intercalation in an organic proton electrolyte with more sluggish intercalation and deintercalation rates [39], [40]. Similar to the result obtained in the H₂SO₄ aqueous electrolyte, the I_{ds} remains constant and starts to drop upon V_{g} reaching a threshold voltage (V_{g}=1.1V, FIG. 14, subplot (a)). The WS₂ nanosheet transforms from a high conductance state to a low conductance state. After the intercalation process (V_{g} was swept from 0 to 3 V), the gate electrode was immediately removed out of the electrolyte and the I_{ds}-V_{ds} of the WS₂ nanosheet was measured. As shown in subplot (b) of FIG. 14, at V_{ds}=0.10V, the I_{ds} drops from 0.24 mA before the proton intercalation to 7.52×10⁻⁸ mA after the proton intercalation, showing an on/off ratio of >10⁶. The large intercalation voltage range (0.96 to 2.01 V, FIG. 14, subplot (a)), compared to that (0.96 to 1.15 V) obtained in the 0.5M H₂SO₄ aqueous electrolyte (FIG. 2, subplot (b)), is consistent with the sluggish intercalation kinetics in the organic electrolyte [40]. It is also worth mentioning that the WS₂ nanosheet intercalated in the organic proton electrolyte shows a similar Raman spectrum compared to that intercalated in the H₂SO₄ aqueous electrolyte (FIG. 15), indicating that WS₂ nanosheets intercalated in the H₂SO₄ aqueous solution and the organic proton electrolyte should have a similar structure. Importantly, the well-maintained low conductance of the nanosheets after the proton intercalation in the organic electrolyte (subplot (b) in FIG. 14) indicates that the obtained intercalated compound in the organic proton electrolyte can be maintained, making it possible to characterize the detailed atomic structures by using transmission electron microscope (TEM).

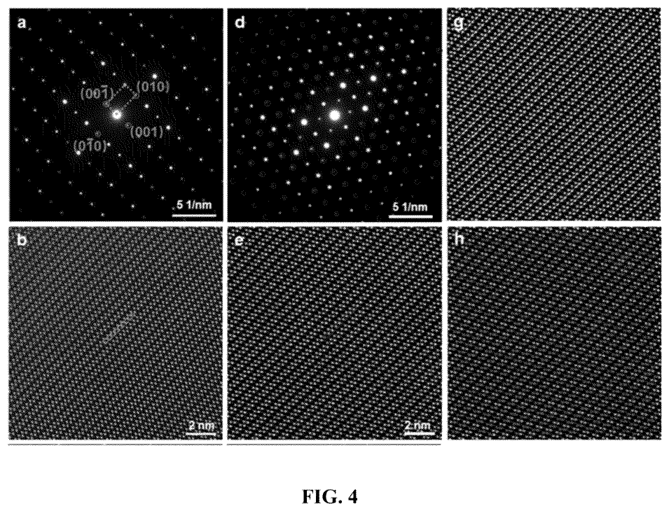

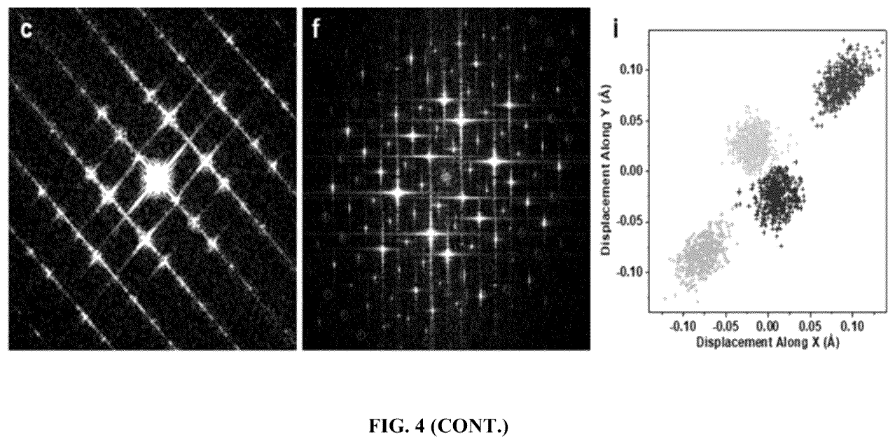

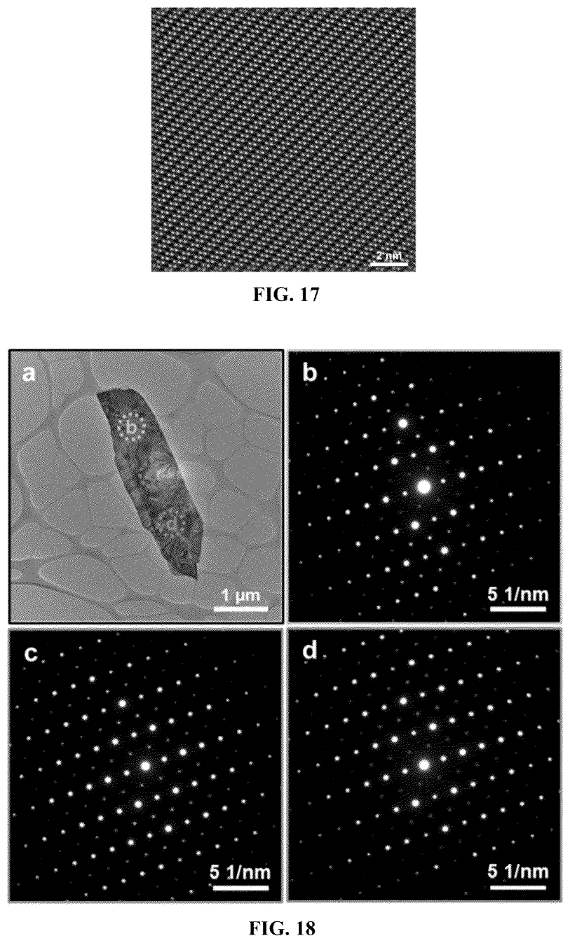

Atomic-resolution HAADF-STEM and SAED were then used to characterize the structure change of WS₂ nanosheet before and after its intercalation in the organic proton electrolyte. As shown in subplot (a) of FIG. 4, the nanosheet before intercalation exhibits a typical diffraction pattern of the 1T′ phase, featuring a lower-symmetry 1×\sqrt{3} rectangular supercell compared to the 1T phase. The HAADF-TEM image (subplot (b) of FIG. 4) shows zigzag chains consisting of two lines of W columns, which is the characteristic of the 1T′ phase. The W-W column distance along the lines is 0.32 nm (subplot (a) of FIG. 16), consistent with the crystal structure refined from single crystal X-ray diffraction in our previous report [35]. The corresponding fast Fourier transform (FFT) pattern (subplot (c) of FIG. 4) is also consistent with the SAED pattern. After the proton intercalation, a new group of super-reflections appears in the SAED pattern (highlighted circles in subplot (d) of FIG. 4), indicating the phase transition from 1T′ to a new structure with a reduced symmetry. The well-preserved zigzag chains in the HAADF-STEM image (subplot (e) of FIG. 4) indicate a similar structure to 1T′-WS₂, but with subtle lattice distortion as reflected by the super-reflection spots in the corresponding FFT pattern (highlighted by circles in subplot (f) of FIG. 4). Damping the amplitude of all the super-reflections allows us to generate a reference image (FIG. 17) corresponding to the 1T′ lattice without lattice distortion [41]. The atomic displacement can then be quantitatively measured by comparing the W-column positions in the raw image (subplot (c) of FIG. 4) and the reference image (FIG. 17). The derived displacement vector field in subplot (g) of FIG. 4 reveals different displacements between the two adjacent lines within every zigzag chain, with large opposite atomic shifts in one line and smaller shifts in the other. The smaller shifts are represented by circles in subplot (h) of FIG. 4, which is only ˜0.03 Å on average (subplot (i) of FIG. 4). Whereas the large opposite shifts, as represented by circles, appear to be along and with a magnitude as large as ˜0.12 Å. It generates one line of W dimers (subplot (g) of FIG. 4, and subplot (b) of FIG. 4) within the zigzag chains, which ambiguously demonstrates a new distorted octahedral structure, denoted as 1T′_{d}, that is distinct from all the reported phases in WS₂. Impressively, the phase transition can occur across the whole nanosheet, demonstrating that the nanosheet has completely transformed from the 1T′ phase to the new 1T′_{d} phase (FIG. 18).

Additional supporting information of the disclosure above is provided in Appendices 1-3.

In summary, we have demonstrated a reversible phase transition strategy driven by proton intercalation and deintercalation, respectively, to inject into and extract electrons out of 1T′-WS₂. The high electron injection and extraction densities (˜1 e per formula unit of WS₂) driven by the proton intercalation and deintercalation enable a completely reversible phase transition between 1T′-WS₂ and the new 1T′_{d}-WS₂, which is confirmed by comprehensive characterizations, including Raman, PL, SAED, and HAADF-STEM. Such a reversible phase transition driven by the proton intercalation and deintercalation opens a new strategy toward the dynamical control of the phase-dependent physicochemical properties of TMDs, which might exhibit potential applications in transistors, memory devices, and neuromorphic computing.

The advantage of achieving reversible phase transition over the whole nanosheet of single-crystalline 1T′-WS₂ material without causing structural damage to the nanosheet can be utilized in designing a transistor for use in electronic and optical applications. An aspect of the present disclosure is to provide a transistor incorporated with a 1T′-WS₂ nanosheet. Since the reversible phase transition occurs over the whole nanosheet rather than limited to a certain active/single layer or localized domains in the nanosheet, this characteristic can be advantageously utilized to enhance a current handling capability of the transistor and to increase a sensitivity of the transistor in responding to an electrical or optical stimulus.

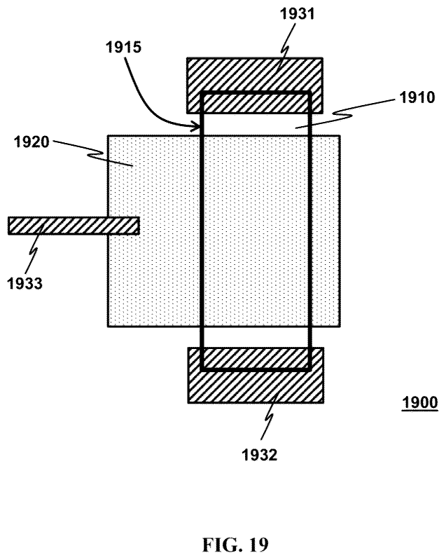

FIG. 19 depicts a structure of an exemplary transistor 1900 as disclosed herein.

The transistor 1900 comprises a source electrode 1932, a drain electrode 1931, a gate electrode 1933, a 1T′-WS₂ nanosheet 1910 and a proton electrolyte 1920. As used herein, “a nanosheet” is a sheet of material having a thickness ranging from 1 to 100 nm. The 1T′-WS₂ nanosheet 1910 forms a channel layer of the transistor 1900. Furthermore, the channel layer, i.e. the 1T′-WS₂ nanosheet 1910, connects the source and drain electrodes 1932, 1931. The nanosheet 1910 has a circumference 1915. Since the nanosheet 1910 has a nanoscale thickness, the circumference 1915 has an appearance resembling an edge. Herein in the present disclosure, the circumference 1915 is also referred to as the edged circumference 1915. The proton electrolyte 1920 is in contact with the edged circumference 1915. The proton electrolyte 1920 may contact the whole edged circumference 1915 or, more practically, may contact only a part of the edged circumference 1915. The proton electrolyte 1920 provides a reservoir of protons for proton intercalation and deintercalation of the nanosheet 1910. Furthermore, the gate electrode 1933 contacts the proton electrolyte 1920 but does not contact the nanosheet 1910. It follows that a non-zero gate-source voltage applied between the gate electrode 1933 and the source electrode 1932 creates a voltage difference between the proton electrolyte 1920 and the nanosheet 1910. This voltage difference controls initiation of an injection process or an extraction process of electrons, thereby triggering the proton intercalation or proton deintercalation. It follows that, also supported by subplot (b) of FIG. 2, the proton electrolyte 1920 is controllable by a gate-source voltage to intercalate or de-intercalate the nanosheet 1910 with protons. The proton intercalation or deintercalation of the nanosheet 1910 is used for inducing a reversible phase transition over the nanosheet 1910 to thereby modify an electrical conductance of the channel layer (i.e. the nanosheet 1910) or a spectral response of the channel layer to light. The modifications to the electrical conductance and to the spectral response to light are supported by subplot (b) of FIG. 2 and subplot (b) of FIG. 3, respectively. Note that the reversible phase transition is between the 1T′ phase and the 1T′_{d} phase. As shown in subplot (a) of FIG. 14, applying the gate-source voltage of 1.1V or above to the transistor 1900 induces the nanosheet 1910 to transit from the 1T′ phase to the 1T′_{d} phase. Also note that the transistor 1900 is a phototransistor if the spectral response of the transistor 1900 to light is utilized in optical applications.

The 1T′-WS₂ nanosheet 1910 can be uniformly crystalline. In certain embodiments, the crystalline regions of the 1T′-WS₂ nanosheet 1910 may account for greater than 90% by volume of the 1T′-WS₂ nanosheet 1910. In other embodiments, the crystalline regions may account for greater than 92%, 95%, 97%, 98%, 99%, or 99.9% of the volume of the 1T′-WS₂ nanosheet 1910. In certain embodiments, the crystalline regions may account for a volume of the 1T′-WS₂ nanosheet 1910 in the range of 70% to 100%, 80% to 100%, 90% to 100%, 90% to 99%, 95% to 100%, 95% to 99%, 96% to 100%, 96% to 99%, 97% to 100%, 97% to 99%, 98% to 100%, 98% to 99%, 99% to 100%, 99.9 to 100%, or any value or range of values within those ranges.

The 1T′-WS₂ nanosheet 1910 can comprise between 2-100 layers of 1T′-WS₂ nanosheet. In certain embodiments, the 1T′-WS₂ nanosheet 1910 comprises 2-90 layers, 2-80 layers, 2-70 layers, 2-60 layers, 2-50 layers, 2-40 layers, 2-30 layers, 2-25 layers, 2-20 layers, 2-15 layers, 2-10 layers, 2-5 layers, 3-30 layers, 3-25 layers, 3-20 layers, 3-15 layers, 3-11 layers, 1-5 layers, 3-5 layers, 1-3 layers, 1-2 layers, or 2-3 layers of 1T′-WS₂ nanosheet.

In certain embodiments, the proton electrolyte 1920 is in liquid form. Those skilled in the art will appreciate that techniques for securely containing a liquid proton electrolyte in the transistor 1900 and exposing the liquid proton electrolyte to at least a part of the edged circumference 1915 are available in the art. As an example, one technique is the arrangement of the microcell device as depicted in subplot (a) of FIG. 2.

In certain embodiments, the proton electrolyte 1920 is an aqueous proton electrolyte. The aqueous proton electrolyte can be an inorganic acid. The inorganic acid can comprise sulfuric acid, nitric acid, hydrochloric acid, phosphoric acid, acetic acid, or a combination thereof.

In certain embodiments, the proton electrolyte 1920 is an organic proton electrolyte. The organic proton electrolyte may comprise TFSI dissolved in liquid poly(ethylene glycol). In certain embodiments, the liquid poly(ethylene glycol) has an average molecular weight of about 600 amu. The organic proton electrolyte can comprise TFSI at a concentration of about 0.18 M.

In certain embodiments, the proton electrolyte 1920 is in solid form. The proton electrolyte 1920 may be a proton-containing solid electrolyte, such as an acid-in-clay electrolyte.

In certain embodiments, the drain and source electrodes 1931, 1932 are made of gold or chromium. Those skilled in the art will appreciate that other conductive materials may be selected to realize the drain and source electrodes 1931, 1932 provided that (1) an ohmic contact is realizable between the 1T′-WS₂ nanosheet 1910 and each of the drain and source electrodes 1931, 1932, and (2) the selected conductive materials are inert to WS₂.

In certain embodiments, the gate electrode 1933 is made of platinum. Similarly, other conductive materials may be selected to realize the gate electrode 1933. The selected conductive materials are required to at least resist corrosion caused by the proton electrolyte 1920.

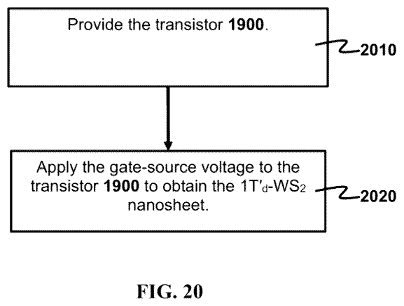

Based on the disclosed transistor 1900, a method of preparing a 1T′_{d}-WS₂ nanosheet is developed. FIG. 20 depicts a flowchart showing exemplary steps of the disclosed method. The method comprises steps 2010 and 2020. In the step 2010, an embodiment of the disclosed transistor 1900 is provided. In the step 2020, the gate-source voltage between the gate electrode 1933 and the source electrode 1932 is applied to the provided embodiment of the transistor 1900. It thereby induces a reversible phase transition of the 1T′-WS₂ nanosheet 1910 from the 1T′ phase to the 1T′_{d} phase, giving the 1T′_{d}-WS₂ nanosheet.

In certain embodiments, each of the 1T′-WS₂ nanosheet and the 1T′_{d}-WS₂ nanosheet comprises at least two layers.

In certain embodiments, each of the 1T′-WS₂ nanosheet and the 1T′_{d}-WS₂ nanosheet is uniformly crystalline.

In certain embodiments, the gate-source voltage is 1.1V or above.

The present invention may be embodied in other specific forms without departing from the spirit or essential characteristics thereof. The present embodiment is therefore to be considered in all respects as illustrative and not restrictive. The scope of the invention is indicated by the appended claims rather than by the foregoing description, and all changes that come within the meaning and range of equivalency of the claims are therefore intended to be embraced therein.

### Appendix 1: Synthesis of 1T′-WS₂ Crystals

The 1T′-WS₂ crystals were synthesized according to our previous work [35]. Specifically, for the synthesis of 1T′-WS₂, the K₂WO₄ and S powder with molar ratio of 1:4 were ground for 10 minutes using a mortar to mix them homogeneously. Subsequently, the mixture was transferred to a quartz ample, which was then vacuumed to Oct. 6, 2010-5 Torr by a molecular pump and sealed by oxyhydrogen flame. After that, the quartz ample was heated to 500° C. at a ramping rate of 1.5° C./min and kept at 500° C. for 96 hours in a box furnace. After cooling down to room temperature naturally, the precursor was loaded in an alumina crucible and transferred to a tube furnace. After purging with Ar for 15 minutes, the tube was moved into the preheated furnace zone at 750° C. and maintained for 8 h under an atmosphere of H₂/Ar (20 s.c.cm/80 s.c.cm) gas. After the reaction, the tube was moved out of the heating zone and quickly cooled down to room temperature within 10 minutes. The resulting product was washed with Milli-Q water until the pH value of the supernatant was between 7 and 8. The product was then kept in Milli-Q water for 12 hours and immersed in an I₂ acetonitrile solution (4 mmol, 15 ml) for 24 hours. After that, the product was washed with acetonitrile and Milli-Q water three times, respectively. After drying in a vacuum oven at room temperature for 24 hours, the 1T′-WS₂ crystals were obtained and used for the device fabrication.

### Appendix 2: Characterization of WS₂ with Unconventional Crystal Phases

Raman spectra were recorded with a Renishaw in Via™ conformal Raman microscope with an excitation wavelength of 532 nm and a low power density of <5 mW/μm² to avoid the phase transition of the metastable WS₂. TEM images and SAED patterns were captured with a JEM-2100F (JEOL) transmission electron microscope. SAED patterns and HAADF-STEM images were captured with a JEM-ARM200F (JEOL) TEM equipped with an advanced aberration corrector and a cold field emission gun. All TEMs operate at an accelerating voltage of 200 kV. The phase of the nanosheets was checked by Raman spectroscopy before TEM characterization.

### Appendix 3: Device Fabrication and Characterization

A set of 32 Au contact pads was prefabricated via the conventional photolithography and thermal evaporation on a 16 mm×16 mm SiO₂ (300 nm)/Si substrate. 1T′-WS₂ nanosheets were mechanically exfoliated from our synthesized 1T′-WS₂ crystals by a Magic™ scotch tape and transferred onto the prefabricated Si substrate. Then, a low-temperature device fabrication process was used to connect the 1T′-WS₂ nanosheets with the prefabricated contact pads. Specifically, the PMMA (495, A8, Microchem) was spin-coated on the 1T′-WS₂ nanosheet at 3,000 r.p.m for 40 s and baked on a hotplate at 55° C. for 20 minutes. Then, an e-beam lithography system (TECAN VEGA) was used to define the electrode contact. Finally, thermally evaporated Cr (8 nm)/Au (32 nm) was used as the contact electrodes. After the lift-off procedure, the device chip was spin-coated with 1-μm-thick PMMA film to passivate the metallic electrodes. A window on the passivated PMMA layer was carved by the e-beam lithography to expose the region of interest for the test. Using one source measurement unit in Keysight 2902A, a direct voltage V_{ds}=0.1V was applied between the drain and source electrodes to measure the current under the gating process. Another source measurement unit was used to apply the gate voltage between the Pt wire and the WS₂ nanosheet and concurrently record the gate current.

As shown in FIG. 5, three types of microcell devices are fabricated in this work. In Type 1, a three-electrode microcell device is used for the in-situ electrical measurement, which can simultaneously collect the drain-source and gate currents during the measurement. In Type 2, a four-electrode microcell device, consisting of the drain, source, gate, and reference electrodes, is used for the cycling stability test, which can maintain stable gate potentials at the solid-electrolyte interface during a prolonged cycling test [42]. In Type 3, a microcell device with in-situ Raman is used to collect the Raman spectra of the nanosheet at different gate potentials.

As shown in FIG. 6, Au contact pads were prefabricated on a SiO₂ (300 nm)/Si substrate (16 mm×16 mm) by the conventional photolithography and then thermal evaporation. The mechanically exfoliated 1T′-WS₂ nanosheets were first transferred onto the substrate. Then, the drain and source electrodes (Cr (8 nm)/Au (32 nm)) were fabricated by a standard e-beam lithography (EBL) process, which contacted two pre-patterned Au pads. Finally, a thick PMMA passivation layer (˜1 μm) was spin-coated on the device, and a window in the designed PMMA area was opened by EBL.

As shown in FIG. 7, the equivalent electrical circuit diagram of a three-electrode microcell device includes two source measurement units (SMUs). The SMU 1 is used to measure the applied voltage (Vas) between the drain and source electrodes of the TMD nanosheet and the current flowing through the drain and source electrodes (I_{ds}) to monitor the transport modulation, in which the “High Force (Force HI)” and “Low Force (Force LO)” are connected with the drain and source electrodes of the TMD nanosheet, respectively. The SMU 2 is used to measure the gate voltage (V_{g}) and gate current (I_{g}), in which the “Force HI” and “Force LO” are connected with the gate electrode (Pt wire) and the ground, respectively. The SMU 1 and SMU 2 are synchronized together, allowing us to record the drain-source and gate current signals simultaneously.

The total number of transferred electrons is obtained by integrating the scan time and current. As shown in FIG. 8, the number of injected electrons (purple area) and the number of extracted electrons are Q₁=1.056×10⁻⁸ C and Q₂=1.048×10⁻⁸ C, respectively. The slight deviation (less than 1%) between Q₁ and Q₂ might arise from the noise current during measurement. The nearly equal numbers of injected and extracted electrons indicate the high reversibility of the electron injection and extraction processes.

The number of transferred electrons per formula unit of WS₂ (n) can be calculated according to the following equations:

$${N}_{{WS}_{2}} = \frac{4 \times A \times d}{{V}_{unit cell}}$$

$$and$$

$$n = \frac{{N}_{{e}^{-}}}{{N}_{{WS}_{2}}} = \frac{Q / q}{{N}_{{WS}_{2}}}$$

where A is the area of WS₂ nanosheet, d is the thickness of WS₂ nanosheet, V_{unit cell}=2.1688×10⁻²⁸ m³ is the volume of the unit cell of WS₂, Q is the quantity of injected or extracted electrons, q=1.60217662×10⁻¹⁹ C is the elementary charge, Nₑ_{^{−}} is the number of transferred electrons, and N_{WS}_{₂} is the number of the formula unit of WS₂. As a result, the calculated injected and extracted electrons per formula unit of WS₂ are n₁=0.9857 and n₂=0.9782, respectively.

As shown in subplot (a) of FIG. 10, the microcell device was tested in a Li-ion polymer gel. Briefly, LiClO₄ (0.3 g. Sigma-Aldrich) and polyethylene oxide (M_{W}=100,000, Sigma-Aldrich) were dissolved in 15 mL of anhydrous methanol, which was stirred for 6 h at 60° C. After that, the gel was dropped onto the device and then dried in a vacuum oven at 80° C. for 10 min to remove the residual solvent prior to the measurement. When the gate voltage is scanned from 0 to 2 V, a low conductivity in the 1T′-WS₂ nanosheet is observed, indicating no reversible transport modulation. Subplot (b) of FIG. 10 shows the device measured in a 0.5M deuterosulfuric acid solution. It is found that deuterium ions only lead to minimal transport modulation of 1T′-WS₂ during the test, indicating that the deuterium ions cannot play the same role as protons to induce the transport modulation.

A four-electrode microcell device (Type 2 in subplots (c) and (d) of FIG. 5, and FIG. 12) was employed to characterize the cycling stability. The reference electrode (Ag/AgCl) was introduced to maintain a stable interfacial gate potential and avoid the influence of polarization during a prolonged operation [42]. During the cycling test, the nanosheet shows a highly reversible transport modulation.

As shown in FIG. 12, the equivalent electrical circuit diagram of a four-electrode microcell device includes two source measurement units (SMUs). The SMU 1 is used to measure the drain-source current (I_{ds}), in which the “High Force (Force HI)” and “Low Force (Force LO)” are connected to the drain and source electrodes of the TMD nanosheet, respectively. The SMU 2 is used to measure the voltage (V_{g}) between the reference electrode (Ag/AgCl) and the nanosheet and the current (I_{g}) flowing through the gate electrode, where the “Low Sense (Sense LO)” and “Low Force (Force LO)” are connected with the TMD nanosheet together. The “High Force (Force HI)” and “High Sense (Sense HI)” are connected with the gate electrode (Pt wire) and reference electrode (Ag/AgCl), respectively. Using such a reference electrode in the cycling test can avoid the influence of polarization and guarantee that the voltage applied to the nanosheet in different cycles is stable [42].

At the constant gate potential of 0.81V, the Raman spectrum shows the peaks of the original 1T′ phase and the emerged new 1T′_{d} phase, indicating their coexistence. When the gate potential slightly increased to 0.82V, the Raman peaks of 1T′-WS₂ disappeared, and only the Raman peaks of the emerged new 1T′_{d} phase can be observed.

The organic proton electrolyte, composed of 0.18 mol L⁻¹ bis(trifluoromethane) sulfonimide (TFSI⁻) dissolved in liquid poly(ethylene glycol) with an average molecular weight (Mₙ) of 600, was used as the proton source for intercalation [39]. As shown in subplot (a) of FIG. 14, the 1T′-WS₂ nanosheet shows a large transport modulation as the gate voltage swept from 0 to 3V. When the gate voltage reached 3V, the gate electrode was immediately removed out of the electrolyte. The I_{ds}-V_{ds} curve of the WS₂ nanosheet was then measured, and donoted as after intercalation. As shown in subplot (b) of FIG. 14, the 1T′-WS₂ nanosheet before the intercalation shows a good linear feature, indicating a metallic characteristic. However, the nanosheet shows an ultralow conductive characteristic after the intercalation process.

The Raman spectra were used to characterize the 1T′-WS₂ nanosheets before and after the proton intercalation. As shown in FIG. 15, the Raman spectrum of the 1T′-WS₂ nanosheet before intercalation is same as that of 1T′-WS₂ reported previously [35]. indicating the phase of the as-prepared nanosheet is a pure 1T′. After intercalated in the organic proton electrolyte, the Raman peaks of the nanosheet corresponding to the 1T′ phase disappear, and a distinct set of new peaks assigned to the new 1T′_{d} phase emerges, which is similar to that of the 1T′-WS₂ nanosheet intercalated in a 0.5M H₂SO₄ aqueous solution. These results suggest that the emerged new phase after proton intercalation in the organic proton electrolyte is similar to that obtained in the H₂SO₄ aqueous solution. The slight Raman peak shifts of 1T′_{d} nanosheets obtained after proton intercalation in the organic proton electrolyte and 0.5M H₂SO₄ aqueous solution can be attributed to the strong electrical field during the in-situ Raman measurement [43], [44].

Three different areas are selected from the 1T′-WS₂ nanosheet after the proton intercalation (FIG. 18). As shown in subplots (b)-(d) of FIG. 18, the SAED patterns of three selected areas all show the characteristic diffraction spots of the 1T′_{d} phase viewed from the same zone axis, indicating that the complete phase transition from 1T′ to 1T′_{d}.

### REFERENCES

There follows a list of references that are occasionally cited in the specification. Each of the disclosures of these references is incorporated by reference herein in its entirety.
[1] Chen, Y.; Lai, Z.; Zhang, X.; Fan, Z.; He, Q.; Tan, C.; Zhang, H., Phase engineering of nanomaterials. Nat. Rev. Chem. 2020, 4, 243-256.
[2] Voiry, D.; Mohite, A.; Chhowalla, M., Phase engineering of transition metal dichalcogenides. Chem. Soc. Rev. 2015, 44, 2702-12.
[3] Lu, N.; Zhang, P.; Zhang, Q.; Qiao, R.; He, Q.; Li, H.-B.; Wang, Y.; Guo, J.; Zhang, D.; Duan, Z.; Li, Z.; Wang, M.; Yang, S.; Yan, M.; Arenholz, E.; Zhou, S.; Yang, W.; Gu, L.; Nan, C.-W.; Wu, J.; Tokura, Y.; Yu, P., Electric-field control of tri-state phase transformation with a selective dual-ion switch. Nature 2017, 546, 124-128.
[4] Wang, Y.; Xiao, J.; Chung, T.-F.; Nie, Z.; Yang, S.; Zhang, X., Direct electrical modulation of second-order optical susceptibility via phase transitions. Nat. Electron. 2021, 4 (10), 725-730.
[5] Wang, Y.; Xiao, J.; Zhu, H.; Li, Y.; Alsaid, Y.; Fong, K. Y.; Zhou, Y.; Wang, S.; Shi, W.; Wang, Y.; Zettl, A.; Reed, E. J.; Zhang, X., Structural phase transition in monolayer MoTe₂ driven by electrostatic doping. Nature 2017, 550, 487-491.
[6] Acerce, M.; Voiry, D.; Chhowalla, M., Metallic 1T phase MoS₂ nanosheets as supercapacitor electrode materials. Nat. Nanotechnol. 2015, 10 (4), 313-318.
[7] Yu, Y.; Nam, G.-H.; He, Q.; Wu, X.-J.; Zhang, K.; Yang, Z.; Chen, J.; Ma, Q.; Zhao, M.; Liu, Z.; Ran, F.-R.; Wang, X.; Li, H.; Huang, X.; Li, B.; Xiong, Q.; Zhang, Q.; Liu, Z.; Gu, L.; Du, Y.; Huang, W.; Zhang, H., High phase-purity 1T′-MoS₂- and 1T′-MoSe₂-layered crystals. Nat. Chem. 2018, 10, 638-643.
[8] Voiry, D.; Yamaguchi, H.; Li, J.; Silva, R.; Alves, D. C.; Fujita, T.; Chen, M.; Asefa, T.; Shenoy, V. B.; Eda, G.; Chhowalla, M., Enhanced catalytic activity in strained chemically exfoliated WS₂ nanosheets for hydrogen evolution. Nat. Mater. 2013, 12, 850-5.
[9] Xu, X.; Pan, Y.; Liu, S.; Han, B.; Gu, P.; Li, S.; Xu, W.; Peng, Y.; Han, Z.; Chen, J.; Gao, P.; Ye, Y., Seeded 2D epitaxy of large-area single-crystal films of the van der Waals semiconductor 2H MoTe₂. Science 2021, 372, 195-200.
Wang, W.; Kim, S.; Liu, M.; Cevallos, F. A.; Cava, R. J.; Ong, N. P., Evidence for an edge supercurrent in the Weyl superconductor MoTe₂. Science 2020, 368, 534-537.
Yuan, Y.; Pan, J.; Wang, X.; Fang, Y.; Song, C.; Wang, L.; He, K.; Ma, X.; Zhang, H.; Huang, F.; Li, W.; Xue, Q.-K., Evidence of anisotropic Majorana bound states in 2M-WS₂. Nat. Phy. 2019, 15, 1046-1051.
Vaňo, V.; Amini, M.; Ganguli, S. C.; Chen, G.; Lado, J. L.; Kezilebieke, S.; Liljeroth, P., Artificial heavy fermions in a van der Waals heterostructure. Nature 2021, 599, 582-586.
Voiry, D.; Goswami, A.; Kappera, R.; Silva, C. d. C. C. e.; Kaplan, D.; Fujita, T.; Chen, M.; Asefa, T.; Chhowalla, M., Covalent functionalization of monolayered transition metal dichalcogenides by phase engineering. Nat. Chem. 2015, 7, 45-49.
Cho, S.; Kim, S.; Kim, J. H.; Zhao, J.; Seok, J.; Keum, D. H.; Baik, J.; Choe, D.-H.; Chang, K. J.; Suenaga, K.; Kim, S. W.; Lee, Y. H.; Yang, H., Phase patterning for ohmic homojunction contact in MoTe₂. Science 2015, 349, 625-628.
Eda, G.; Fujita, T.; Yamaguchi, H.; Voiry, D.; Chen, M.; Chhowalla, M., Coherent Atomic and Electronic Heterostructures of Single-Layer MoS₂. ACS Nano 2012, 6, 7311-7317.
Xiong, F.; Wang, H.; Liu, X.; Sun, J.; Brongersma, M.; Pop, E.; Cui, Y., Li Intercalation in MoS₂: In Situ Observation of Its Dynamics and Tuning Optical and Electrical Properties. Nano Lett. 2015, 15, 6777-6784.
Duerloo, K. A.; Li, Y.; Reed, E. J., Structural phase transitions in two-dimensional Mo- and W-dichalcogenide monolayers. Nat. Commun. 2014, 5, 4214.
Lin, Y.-C.; Dumcenco, D. O.; Huang, Y.-S.; Suenaga, K., Atomic mechanism of the semiconducting-to-metallic phase transition in single-layered MoS₂. Nat. Nanotechnol. 2014, 9, 391-396.
Zhang, X.; Luo, Z.; Yu, P.; Cai, Y.; Du, Y.; Wu, D.; Gao, S.; Tan, C.; Li, Z.; Ren, M.; Osipowicz, T.; Chen, S.; Jiang, Z.; Li, J.; Huang, Y.; Yang, J.; Chen, Y.; Ang, C. Y.; Zhao, Y.; Wang, P.; Song, L.; Wu, X.; Liu, Z.; Borgna, A.; Zhang, H., Lithiation-induced amorphization of Pd₃P₂S₈ for highly efficient hydrogen evolution. Nat. Catal. 2018, 1, 460-468.
Zakhidov, D.; Rehn, D. A.; Reed, E. J.; Salleo, A., Reversible Electrochemical Phase Change in Monolayer to Bulk-like MoTe₂ by Ionic Liquid Gating. ACS Nano 2020, 14, 2894-2903.
Zhang, F.; Zhang, H.; Krylyuk, S.; Milligan, C. A.; Zhu, Y.; Zemlyanov, D. Y.; Bendersky, L. A.; Burton, B. P.; Davydov, A. V.; Appenzeller, J., Electric-field induced structural transition in vertical MoTe₂- and Mo₁₋ₓWₓTe₂-based resistive memories. Nat. Mater. 2019, 18, 55-61.
Zhou, J.; Lin, Z.; Ren, H.; Duan, X.; Shakir, I.; Huang, Y.; Duan, X., Layered Intercalation Materials. Adv. Mater. 2021, 33, 2004557.
Wu, Y.; Li, D.; Wu, C.-L.; Hwang, H. Y.; Cui, Y., Electrostatic gating and intercalation in 2D materials. Nat. Rev. Mater. 2023, 8, 41-53.
Kappera, R.; Voiry, D.; Yalcin, S. E.; Branch, B.; Gupta, G.; Mohite, A. D.; Chhowalla, M., Phase-engineered low-resistance contacts for ultrathin MoS₂ transistors. Nat. Mater. 2014, 13, 1128-1134.
Zeng, Z.; Yin, Z.; Huang, X.; Li, H.; He, Q.; Lu, G.; Boey, F.; Zhang, H., Single-layer semiconducting nanosheets: high-yield preparation and device fabrication. Angew. Chem. 2011, 123, 11289-11293.
Wang, C.; He, Q.; Halim, U.; Liu, Y.; Zhu, E.; Lin, Z.; Xiao, H.; Duan, X.; Feng, Z.; Cheng, R.; Weiss, N. O.; Ye, G.; Huang, Y.-C.; Wu, H.; Cheng, H.-C.; Shakir, I.; Liao, L.; Chen, X.; Goddard Iii, W. A.; Huang, Y.; Duan, X., Monolayer atomic crystal molecular superlattices. Nature 2018, 555, 231-236.
He, Q.; Lin, Z.; Ding, M.; Yin, A.; Halim, U.; Wang, C.; Liu, Y.; Cheng, H.-C.; Huang, Y.; Duan, X., In Situ Probing Molecular Intercalation in Two-Dimensional Layered Semiconductors. Nano Lett. 2019, 19, 6819-6826.
Gong, Y.; Yuan, H.; Wu, C.-L.; Tang, P.; Yang, S.-Z.; Yang, A.; Li, G.; Liu, B.; van de Groep, J.; Brongersma, M. L.; Chisholm, M. F.; Zhang, S.-C.; Zhou, W.; Cui, Y., Spatially controlled doping of two-dimensional SnS₂ through intercalation for electronics. Nat. Nanotechnol. 2018, 13, 294-299.
Qian, Q.; Ren, H.; Zhou, J.; Wan, Z.; Zhou, J.; Yan, X.; Cai, J.; Wang, P.; Li, B.; Sofer, Z.; Li, B.; Duan, X.; Pan, X.; Huang, Y.; Duan, X., Chiral molecular intercalation superlattices. Nature 2022, 606, 902-908.
Li, L.; Wang, M.; Zhou, Y.; Zhang, Y.; Zhang, F.; Wu, Y.; Wang, Y.; Lyu, Y.; Lu, N.; Wang, G.; Peng, H.; Shen, S.; Du, Y.; Zhu, Z.; Nan, C.-W.; Yu, P., Manipulating the insulator-metal transition through tip-induced hydrogenation. Nat. Mater. 2022, 21, 1246-1251.
Zhao, Q.; Liu, L.; Yin, J.; Zheng, J.; Zhang, D.; Chen, J.; Archer, L. A., Proton Intercalation/De-Intercalation Dynamics in Vanadium Oxides for Aqueous Aluminum Electrochemical Cells. Angew. Chem. Int. Ed. 2020, 59, 3048-3052.
Wang, X.; Xie, Y.; Tang, K.; Wang, C.; Yan, C., Redox Chemistry of Molybdenum Trioxide for Ultrafast Hydrogen-Ion Storage. Angew. Chem. Int. Ed. 2018, 57, 11569-11573.
Tan, A. J.; Huang, M.; Avci, C. O.; Büttner, F.; Mann, M.; Hu, W.; Mazzoli, C.; Wilkins, S.; Tuller, H. L.; Beach, G. S. D., Magneto-ionic control of magnetism using a solid-state proton pump. Nat. Mater. 2019, 18, 35-41.
Huang, M.; Hasan, M. U.; Klyukin, K.; Zhang, D.; Lyu, D.; Gargiani, P.; Valvidares, M.; Sheffels, S.; Churikova, A.; Büttner, F.; Zehner, J.; Caretta, L.; Lee, K.-Y.; Chang, J.; Wang, J.-P.; Leistner, K.; Yildiz, B.; Beach, G. S. D., Voltage control of ferrimagnetic order and voltage-assisted writing of ferrimagnetic spin textures. Nat. Nanotechnol. 2021, 16, 981-988.
Lai, Z.; He, Q.; Tran, T. H.; Repaka, D. V. M.; Zhou, D. D.; Sun, Y.; Xi, S.; Li, Y.; Chaturvedi, A.; Tan, C.; Chen, B.; Nam, G. H.; Li, B.; Ling, C.; Zhai, W.; Shi, Z.; Hu, D.; Sharma, V.; Hu, Z.; Chen, Y.; Zhang, Z.; Yu, Y.; Renshaw Wang, X.; Ramanujan, R. V.; Ma, Y.; Hippalgaonkar, K.; Zhang, H., Metastable 1T′-phase group VIB transition metal dichalcogenide crystals. Nat. Mater. 2021, 20, 1113-1120.
Ye, J. T.; Zhang, Y. J.; Akashi, R.; Bahramy, M. S.; Arita, R.; Iwasa, Y., Superconducting Dome in a Gate-Tuned Band Insulator. Science 2012, 338, 1193-1196.
Perera, M. M.; Lin, M.-W.; Chuang, H.-J.; Chamlagain, B. P.; Wang, C.; Tan, X.; Cheng, M. M.-C.; Tománek, D.; Zhou, Z., Improved Carrier Mobility in Few-Layer MoS₂ Field-Effect Transistors with Ionic-Liquid Gating. ACS Nano 2013, 7, 4449-4458.
Illarionov, Y. Y.; Knobloch, T.; Jech, M.; Lanza, M.; Akinwande, D.; Vexler, M. I.; Mueller, T.; Lemme, M. C.; Fiori, G.; Schwierz, F.; Grasser, T., Insulators for 2D nanoelectronics: the gap to bridge. Nat. Commun. 2020, 11, 3385.
Li, S.; Li, J.; Wang, Y.; Yu, C.; Li, Y.; Duan, W.; Wang, Y.; Zhang, J., Large transport gap modulation in graphene via electric-field-controlled reversible hydrogenation. Nat. Electron. 2021, 4, 254-260.
He, P.; Zhang, X.; Wang, Y.-G.; Cheng, L.; Xia, Y.-Y., Lithium-Ion Intercalation Behavior of LifePO₄ in Aqueous and Nonaqueous Electrolyte Solutions. J. Electrochem. Soc. 2008, 155, A144.
Goodge, B. H.; El Baggari, I.; Hong, S. S.; Wang, Z.; Schlom, D. G.; Hwang, H. Y.; Kourkoutis, L. F., Disentangling Coexisting Structural Order Through Phase Lock-In Analysis of Atomic-Resolution STEM Data. Microsc. Microanal. 2022, 28, 404-411.
Pu, J.; Funahashi, K.; Chen, C.-H.; Li, M.-Y.; Li, L.-J.; Takenobu, T., Highly Flexible and High-Performance Complementary Inverters of Large-Area Transition Metal Dichalcogenide Monolayers. Adv. Mater. 2016, 28, 4111-4119.
Ayars, E. J.; Hallen, H. D.; Jahncke, C. L., Electric Field Gradient Effects in Raman Spectroscopy. Phy. Rev. Lett. 2000, 85, 4180-4183.
Li, L.; Lee, I.; Lim, D.; Kang, M.; Kim, G.-H.; Aoki, N.; Ochiai, Y.; Watanabe, K.; Taniguchi, T., Raman shift and electrical properties of MoS₂ bilayer on boron nitride substrate. Nanotechnol. 2015, 26, 295702.

What is claimed is:

1. A transistor comprising:
a source electrode, a drain electrode and a gate electrode;
a 1T′-tungsten disulfide (1T′-WS₂) nanosheet forming a channel layer connecting the source and drain electrodes, the nanosheet having an edged circumference; and
a proton electrolyte in contact with the edged circumference for providing a reservoir of protons for proton intercalation and deintercalation of the nanosheet, wherein the gate electrode contacts the proton electrolyte without contacting the nanosheet such that the proton electrolyte is controllable by a gate-source voltage applied between the gate electrode and the source electrode to intercalate or de-intercalate the nanosheet with protons for inducing a reversible phase transition over the nanosheet to thereby modify an electrical conductance of the channel layer or a spectral response of the channel layer to light.

2. The transistor of claim 1, wherein the 1T′-WS₂ nanosheet comprises at least two layers.

3. The transistor of claim 1, wherein the 1T′-WS₂ nanosheet is uniformly crystalline.

4. The transistor of claim 1, wherein the proton electrolyte is an aqueous proton electrolyte.

5. The transistor of claim 4, wherein the aqueous proton electrolyte is an inorganic acid.

6. The transistor of claim 5, wherein the inorganic acid comprises sulfuric acid, nitric acid, hydrochloric acid, phosphoric acid, acetic acid, or a combination thereof.

7. The transistor of claim 1, wherein the proton electrolyte is an organic proton electrolyte.

8. The transistor of claim 7, wherein the organic proton electrolyte is bis(trifluoromethane) sulfonimide (TFSI) dissolved in poly(ethylene glycol).

9. The transistor of claim 1, wherein the proton electrolyte is a proton-containing solid electrolyte.

10. The transistor of claim 1, wherein each of the drain and source electrodes comprises gold, chromium, or a combination thereof.

11. The transistor of claim 1, wherein the gate electrode comprises platinum.

12. A method of preparing a 1T′_{d}-tungsten disulfide (1T′_{d}-WS₂) nanosheet, the method comprising:
providing the transistor of claim 1; and
applying the gate-source voltage between the gate electrode and the source electrode thereby forming the 1T′_{d}-WS₂ nanosheet.

13. The method of claim 12, wherein each of the 1T′-WS₂ nanosheet and the 1T′_{d}-WS₂ nanosheet comprises at least two layers.

14. The method of claim 12, wherein each of the 1T′-WS₂ nanosheet and the 1T′_{d}-WS₂ nanosheet is uniformly crystalline.

15. The method of claim 12, wherein the gate-source voltage is 1.1V or above.
